(19) United States
(12) Patent Application Publication
(10) Pub. No.: US 2025/0232896 A1
(43) Pub. Date: Jul. 17, 2025

(54) HTS TAPE WITH IMPROVED TRANSVERSE CONDUCTANCE

(71) Applicant: Tokamak Energy Ltd, Abingdon Oxfordshire (GB)

(72) Inventors: Greg Brittles, Abingdon Oxfordshire (GB); Matthew Bristow, Abingdon Oxfordshire (GB)

(21) Appl. No.: 18/854,278

(22) PCT Filed: Apr. 5, 2023
(86) PCT No.: PCT/EP2023/059026

§ 371 Date: Oct. 4, 2024

(30) Foreign Application Priority Data
Apr. 8, 2022 (GB) 2205209.6

(51) Int. Cl. H01B 12/06

(52) U.S. Cl. CPC H01B 12/06

(57) ABSTRACT

A high temperature superconducting, HTS, tape. The HTS tape comprises a superconducting layer a superconducting layer formed from HTS material, a substrate, and one or more buffer layers separating the superconducting layer from the substrate. The HTS tape further comprises a plurality of holes extending at least through the superconducting layer and the one or more buffer layers and conductive material within each hole. The conductive material provides an electrical connection to the superconducting layer through the one or more buffer layers via the hole.

### FIELD OF THE INVENTION

The present invention relates to high temperature superconductors, in particular to high temperature superconducting ReBCO tape.

### BACKGROUND

Superconducting materials are typically divided into “high temperature superconductors” (HTS) and “low temperature superconductors” (LTS). LTS materials, such as Nb and NbTi, are metals or metal alloys whose superconductivity can be described by BCS theory. All low temperature superconductors have a self-field critical temperature (the temperature above which the material cannot be superconducting even in zero external magnetic field) below about 30K. The behaviour of HTS material is not described by BCS theory, and such materials may have self-field critical temperatures above about 30K. The most commonly used HTS are “cuprate superconductors”—ceramics based on cuprates (compounds containing a copper oxide group), such as BSCCO, or ReBCO (where Re is a rare earth element, commonly Y or Gd). Other HTS materials include iron pnictides (e.g. FeAs and FeSe) and magnesium diborate (MgB₂).

ReBCO superconductors are typically manufactured as tapes approximately 100 micrometres thick and with a width of between 2 mm and 12 mm. The structure of a typical tape is illustrated in FIG. 1 and includes a substrate 101 (typically an electropolished nickel-molybdenum alloy, e.g Hastelloy™ approximately 50 micrometres thick), on which is deposited a series of buffer layers known as the buffer stack 102, of approximate thickness 0.2 micrometres. An epitaxial ReBCO-HTS layer 103 overlays the buffer stack, and is typically 1 micrometre thick. A 1-2 micrometre silver layer 104 and a copper stabilizer layer 105 are deposited on and often completely encapsulate the tape. The silver layer 104 and copper stabilizer layer 105 extend continuously around the perimeter of the tape 100 (not illustrated in FIG. 1 for clarity) and may therefore also be referred to as “cladding”. The silver layer 104 makes a low resistivity electrical interface to, and an hermetic protective seal around, the ReBCO layer 103, whilst the copper layer 105 enables external connections to be made to the tape (e.g. by soldering) from either face and provides a parallel conductive path for electrical stabilisation.

“Exfoliated” HTS tape can be manufactured, which lacks a substrate and buffer stack, but typically has a “surrounding coating” of silver. Tape which has a substrate can be referred to as “substrated” HTS tape.

An HTS cable comprises one or more HTS tapes, which are connected along their length via conductive material (normally copper). The HTS tapes may be stacked (i.e. arranged such that the HTS layers are parallel), or they may have some other arrangement of tapes, which may vary along the length of the cable. Notable special cases of HTS cables are single HTS tapes, and HTS pairs. HTS pairs comprise a pair of HTS tapes, arranged such that the HTS layers are parallel. Where substrated tape is used, HTS pairs may be type-0 (with the HTS layers facing each other), type-1 (with the HTS layer of one tape facing the substrate of the other), or type-2 (with the substrates facing each other). Cables comprising more than 2 tapes may arrange some or all of the tapes in HTS pairs. Stacked HTS tapes may comprise various arrangements of HTS pairs, most commonly either a stack of type-1 pairs or a stack of type-0 pairs (or, equivalently, type-2 pairs). HTS cables may comprise a mix of substrated and exfoliated tape.

A superconducting magnet is formed by arranging HTS cables (or individual HTS tapes, which for the purpose of this description can be treated as a single-tape cable) into coils, either by winding the HTS cables or by providing sections of the coil made from HTS cables and joining them together. Turns of the coil may be insulated, non-insulated, or partially insulated by having a controlled resistance between turns, as described in WO2019/150123, for example.

Due to the layered structure of the HTS tape, low resistance joints can be made only to the surface of the tape closest to the HTS layer (i.e. the “HTS side”). The opposite surface, closest to the substrate (the “substrate side”) will inevitably have greater resistance between the HTS and any joint on that surface. FIG. 2 shows an HTS tape 200 with a first joint to a first conductor 210 and a second joint to a second conductor 220. The HTS tape comprises an HTS layer 201, a substrate 202, buffer layers (not shown) which separate the HTS layer and substrate, and a copper or other metal cladding 203. Silver layers and other layers as described above may also be present. The first conductor 210 is placed on the HTS side of the tape 200, allowing current to flow directly in a path 211 from the HTS layer 201 through the entire surface of the copper cladding 203 on that side. In contrast, current to the second conductor 220 cannot pass directly from the HTS layer 201 into the substrate 202 and then to the copper cladding and second conductor, as the buffer layers of the HTS tape 200 are insulating. As such, current flows in a path 221 via the copper cladding at the edges of the tape. This path 221 is longer and has a lower cross sectional area than the path 211 taken by current flowing to the first conductor 210, and therefore has a higher resistance. This limits the ability to make low resistance joints for certain configurations of HTS tapes. This effect also increases the turn to turn resistance for non-insulated and partially insulated coils.

One option to overcome this issue is the use of exfoliated tapes, as described previously. However, exfoliated tapes are generally more fragile than substrated tapes, and expensive to acquire in significant lengths.

### SUMMARY

According to a first aspect there is provided a high temperature superconducting, HTS, tape. The HTS tape comprises a superconducting layer formed from HTS material, a substrate, and one or more buffer layers separating the superconducting layer from the substrate. The HTS tape further comprises a plurality of holes extending at least through the superconducting layer and the one or more buffer layers and conductive material within each hole. The conductive material provides an electrical connection to the HTS material of the superconducting layer through the one or more buffer layers via the hole.

According to a second aspect, there is provided a method of modifying an HTS tape. An HTS tape is provided, the HTS tape having: a superconducting layer formed from HTS material; a substrate; and one or more buffer layers separating the superconducting layer from the substrate. A plurality of holes are formed through at least the superconducting layer and buffer layers of the HTS tape. Conductive material is provided within the holes, such that the conductive material provides an electrical connection to the HTS material of the superconducting layer through the one or more buffer layers via the hole. For example, the conductive material is electrically connected to the substrate and the HTS layer.

According to a third aspect, there is provided method of manufacturing a high temperature superconducting, HTS, tape. A substrate is provided, the substrate having a plurality of holes extending from a first surface of the substrate at least part way through the substrate. One or more buffer layers are deposited on the first surface of the substrate. A high temperature superconducting, HTS, material is deposited on the buffer layers. The buffer layers and HTS material are not deposited over the holes in the substrate. Conductive material is provided within the holes, such that the conductive material provides an electrical connection to the HTS material of the superconducting layer through the one or more buffer layers via the hole. For example, the conductive material is electrically connected to the substrate and the HTS material.

According to a fourth aspect, there is provided a High Temperature Superconductor, HTS, field coil. The HTS field coil comprises windings of one or more HTS tapes about an axis of the coil, wherein the or each HTS tape is an HTS tape according to the first aspect or is an HTS tape modified or manufactured according to the second or third aspects, respectively.

According to a fifth aspect, there is provided a high temperature superconducting, HTS, cable comprising a plurality of HTS tapes according to the first aspect, or a plurality of HTS tapes modified or manufactured according to the second or third aspects, respectively.

HTS tapes embodying the present invention typically also include at least one conductive layer, e.g., a metal layer such as the silver and/or copper cladding illustrated in FIG. 1. Conductive layer(s) may overlay either or both of the substrate or the superconducting layer on the opposite side to the intervening buffer layer(s).

In use, embodiments of the present invention provide a path through which current can flow from the HTS material and through the hole provided in the at least one buffer layer via the conductive material.

### BRIEF DESCRIPTION OF THE DRAWINGS

FIG. 1 illustrates the construction of an HTS tape;

FIG. 2 shows an HTS tape joined to two conductors;

FIG. 3A shows an HTS tape with a plurality of holes;

FIG. 3B shows the HTS tape of FIG. 3A after filling with conductive material;

FIGS. 4A to 4C show different arrangements of holes in an HTS tape;

FIG. 5 shows an HTS tape having blind holes into the substrate;

FIG. 6 shows a section of an HTS coil;

FIG. 7 illustrates the directional terms used herein.

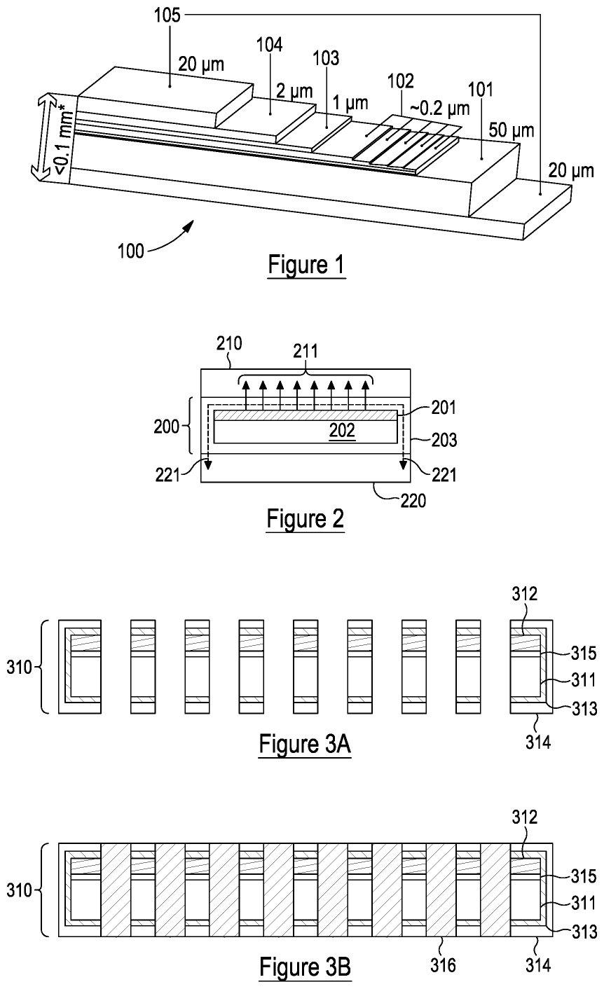

### DETAILED DESCRIPTION

In order to provide reduced resistance for current flow between the HTS and substrate sides of a tape, an HTS tape is proposed herein which has holes through at least the HTS layer and the electrically insulating buffer layer(s). The holes are at least partially filled in by an electrically conductive material, such as a metal or metal alloy. The conductive material provides a path for current to flow from the substrate side of the tape to the HTS layer through the one or more electrically insulating buffer layers via the holes.

FIG. 3A shows an HTS tape 310 having a substrate 311, HTS layer 312, silver coating 313, copper cladding 314, and at least one electrically insulating buffer layer 315 between the HTS layer and the substrate. The HTS tape has a plurality of holes 320 which pass through the full thickness of the HTS tape. Each hole 320 is shown having a constant size and shape through the HTS tape 310, though holes that are tapered, conical, or otherwise non-uniform over their depth are also possible. FIG. 3B shows the same HTS tape 310 after the holes are filled with metal or other conductive material 316, to form conductive paths through the buffer layer 315.

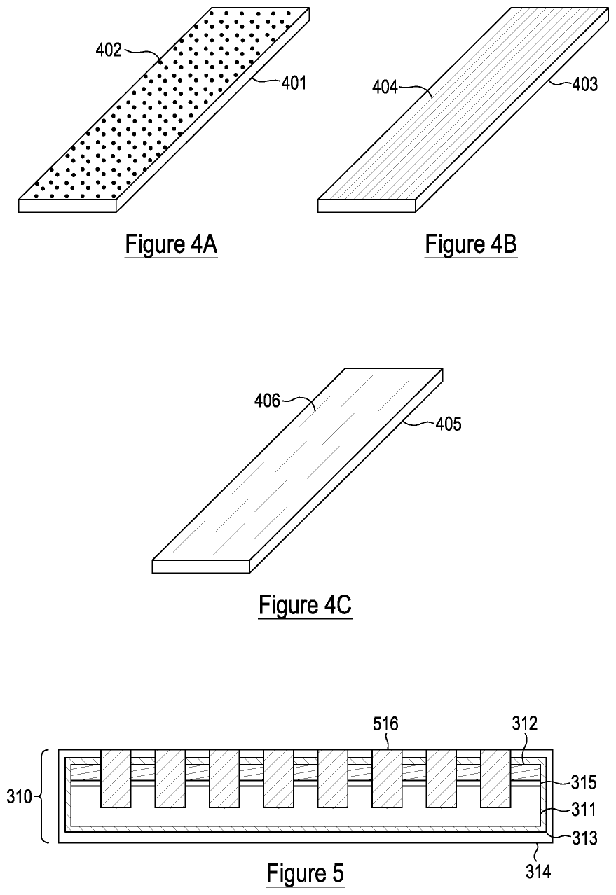

The holes may have any suitable size, shape, spacing, spatial density, arrangement, or geometry. Each of these attributes and the depth of blind holes may be constant across the surface of the tape or may vary regularly or irregularly. For example, FIG. 4A shows an HTS tape 401 having an array of substantially circular holes 402 through it, though other shapes are possible. The array may be a regular square, rectangular or hexagonal lattice, for example, for simplicity both in modelling of the expected result and in forming the holes. Each hole may have a cross-section that is substantially uniform in both linear dimensions, having equal or near equal proportions. Alternatively, the holes may be elongated and extend in one dimension markedly more than another. For example, FIG. 4B shows an HTS tape 403 split into filaments by a series of elongated linear holes 404 (i.e., striations) which extend along the HTS tape. As a yet further example, FIG. 4C shows an HTS tape 405 with a series of elongated linear holes 406 which each extend a short distance along the HTS tape. Elongated holes may also follow a curved or other non-linear path. The depth of an elongated blind hole into the substrate 311 (as described in more detail below in connection with FIG. 5) may vary over its length or become a through hole over some stretches.

The holes are small or, in the case of elongated holes, narrow compared to the width of the tape. Thus, FIG. 3A, as with all the figures, is not drawn to scale. For example, holes will generally have a minimum or minor width (e.g., the diameter of a substantially circular hole or the width of a striation) of 1 micrometre to 1 millimetre, more preferably 10 to 100 micrometres. The spacing between the centres of adjacent holes may be from 2 to 10 times their diameter, for example.

In general, to ensure that a superconducting path exists along the tape, it is desirable for all the remaining ReBCO, or other HTS material, to be electrically connected to at least the ends of the tape via other ReBCO (e.g. in a striated tape with striations extending the full length of the tape), and/or for the remaining ReBCO to form a connected surface, i.e. a surface where each point can be connected to each other point without leaving the surface. Geometries which do not follow either of these limitations are possible, and may be desirable e.g. for specific joint configurations or to provide separated regions of superconductor within the tape for other purposes. Along the tape, in the direction of current flow, arranging the holes such there are no blocked or restricted superconducting paths (e.g., no dead ends) will ensure minimum reduction in current density or critical current of the HTS tape. Control over current density across the tape and other desired effects may be provided by deliberating creating meandering paths through the superconducting material along the tape. For example, holes may be arranged in a regular lattice that is angled relative to the length of the tape to provide a meandering current path along the tape.

As shown in FIG. 5, it is also possible to provide an HTS tape where the holes extend through the HTS 312 and buffer layers 315 of the tape 310 (from the HTS side) without extending completely through the substrate 311, i.e., where the holes are blind holes into the substrate 311. As with the through holes of FIGS. 3A and 3B, the blind holes are filled with conductive material 516 which provides an electrical connection between the HTS layer 312 and the substrate 311 through the buffer layer 315. Typical metal alloy substrates are conductive, so this still achieves the advantages of reducing the resistance by providing alternative current paths.

The resistance through the tape will depend on the size, spacing, geometry, and number of holes provided. This can be modelled analytically and/or numerically using techniques as known in the art. The resistance will also depend on the depth of the holes, and the material used to fill them—i.e. a higher resistivity material within the holes will cause a greater resistance through the tape than a lower resistivity material for the same hole geometry, and where the substrate is a higher resistivity than the material used to fill the holes, the deeper the hole extends into the substrate, the less the resistance will be (and vice versa if the substrate is lower resistivity than the material filling the holes).

For further fine-tuning of the resistance, an insulating layer may be provided on the sides of the holes between the conductive material filling each hole and the substrate (i.e., prior to filling each hole with conductive material). This means that the resistance depends more simply on the geometry of the holes and the resistivity of the material filling them, without the need to consider lateral flow of current through the substrate.

The greatest reduction in resistance will generally be obtained by a larger total cross sectional area of the holes in the HTS tape. However, a greater area of holes also reduces the critical current of the HTS tape, due to there being less ReBCO to provide a superconducting path. As such, the desired geometry will be a balance of the required resistance and critical current for the tape, both of which can be modelled by methods known in the art. As mentioned above, the arrangement of the holes should not cause an actual break in the tape. For example, a hole extending across the width of the HTS tape would not be suitable, as this would be a break in the superconducting path. Instead, the holes should be such that each region of ReBCO on the tape is connected at least to each end of the tape, and optionally to each other region of ReBCO, via a continuous path through ReBCO.

In addition to providing a resistive path through the tape, the holes in the tape will also act to reduce screening currents in a similar manner to striated tape, i.e. the holes will create obstructions within the superconducting material which will constrain the lengths and widths of screening currents produced in the HTS. An array of holes arranged to create meandering current paths along the tape may be used an alternative to substantially full tape-length striations as a technique for reducing screening currents. This effect occurs regardless of whether the holes are filled with conductive material.

The pattern of holes, including their number, spacing, size, or other properties, may be varied along the length of the tape, e.g. to provide different resistance or critical current characteristics in different areas of the tape.

Where the holes extend into the substrate, a large cross sectional area of holes may be undesirable due to mechanical considerations, i.e. cutting through too much of the tape may weaken it too much. However, this may be mitigated by providing specific hole patterns (e.g. the pattern of FIG. 4C will be stronger than the pattern of FIG. 4B, due to the increased links between the uncut regions), or by choice of material to fill the holes.

The holes may be formed by any suitable technique, for example:
Ablative cutting (e.g. laser cutting, electron beam cutting, or ion beam cutting) may be used to cut through the HTS tape to the desired depth. This will cause some heat damage to surrounding areas of HTS, depending on the type of ablative cutting used, the intensity, and the pulse duration. Through holes in HTS tapes with diameters of 20 micrometres have been shown to be possible to produce with negligible damage to the surrounding ReBCO.
Mechanical punching, drilling, scribing, or slitting of the tape can be used to produce holes of around 100 micrometre width. This will result in some cracking of the ReBCO.
Chemical etching can be used to create holes of 10 to 100 micrometre precision (and even less with advanced photolithography processes), and can be used to dissolve metals (e.g. copper and silver) and ReBCO with minimal damage to the surrounding material. However, the buffer layers are generally less susceptible to chemical attack, so chemical etching would likely be used in combination with one of the methods above—i.e. by etching down through the outer cladding layers of the tape and the HTS to expose the buffer layers in the holes, and then using an alternative method (e.g. mechanical or laser cutting) to make a hole through the buffer layer within the holes created by the chemical etching. The holes created through the buffer layer may be smaller than those created by chemical etching, to avoid heat or mechanical stresses to the ReBCO layer during their creation.

Different hole forming techniques may create in holes that are tapered or are otherwise non-uniform in size as they pass through the HTS tape. For example, using a low power or low intensity laser during ablative cutting may result in a hole that is larger where the laser enters the HTS tape than at the exit point of a through hole or at the base of a blind hole. In general, the greater the intensity of a laser or other cutting beam, the closer to parallel the sides of the hole will be. If a tapered hole is cut from the substrate side of the HTS tape, the widest part of the hole will be in the substrate 311, minimising damage to, and removal of material from, the HTS layer 312.

As an alternative to cutting holes into an HTS tape, the HTS tape may be created with the holes in-situ. This may be achieved, for example, by providing a substrate which has the holes in place and depositing the buffer layers and HTS material onto this substrate, which will then result in an HTS tape having the required holes. The holes can then be filled with a suitable conductive material. The initial holes in the substrate may be blind holes if some conduction through the substrate is desired. Other than the provision of the substrate, the deposition of the buffer layers and HTS layer is performed according to conventional techniques, e.g. pulsed laser deposition (PLD), chemical vapour deposition (CVD), chemical solution deposition (CSD), reactive co-evaporation (RCE), etc. In all cases, a film of macroscopically uniform material is grown on the tape surface, with thicknesses from nanometre to micrometre scale.

Suitable electrically conductive materials for filling the holes include a metal or metal alloy (e.g. silver, copper, additional cladding material, or a solder), a semiconductor, a metal-insulator transition material, or a composite material. The conductive material 316 may be applied in a liquid or molten state. High temperatures can damage the HTS layer 312 such that using a solder with a low melting point may be beneficial. Using solders or other liquid-state materials with a low surface tension may help ensure the holes are substantially filled with material, with few voids, to provide a good electrical path through the buffer layers 315. Electroplating and similar techniques may also be used to at least partly fill the holes with conductive material.

Some conductive materials may react with the different layers of HTS tape after filing the hole. For example, some solders react with and dissolve silver over time. A solder with a high silver content, near the saturation point, can be used to prevent long term damage to the silver coating 313.

Forming and subsequently filling holes may cause damage to the superconducting material around the hole. For example, a region around a hole will be damaged by the heat generated during laser cutting, while solder and some other filling materials will damage any superconducting material they come into physical contact with. Damaged superconducting material becomes insulating and is unable to carry a current even at cryogenic temperatures. In such cases, the alternative current path created through the insulating buffer layers will be from undamaged superconducting material 312, into an overlaying metal layer 313, 314 to bypass the damaged region, and from there to the conductive material 316 in the hole (or vice versa). Testing has shown that damage to superconducting material caused by laser cutting and then filling the holes with solder is limited to a region surrounding each hole roughly 10 to 20 micrometres wide.

When used to form a high temperature superconducting magnet or an HTS cable, the HTS tape described above provides improved conductivity between stacked HTS tapes. For example, when wound into a pancake coil (i.e. a simple coil where the HTS is wound in a manner similar to a spool of ribbon), the HTS tape described above will provide reduced radial resistance between turns of the coil, and this resistance may be easily controlled as described above.

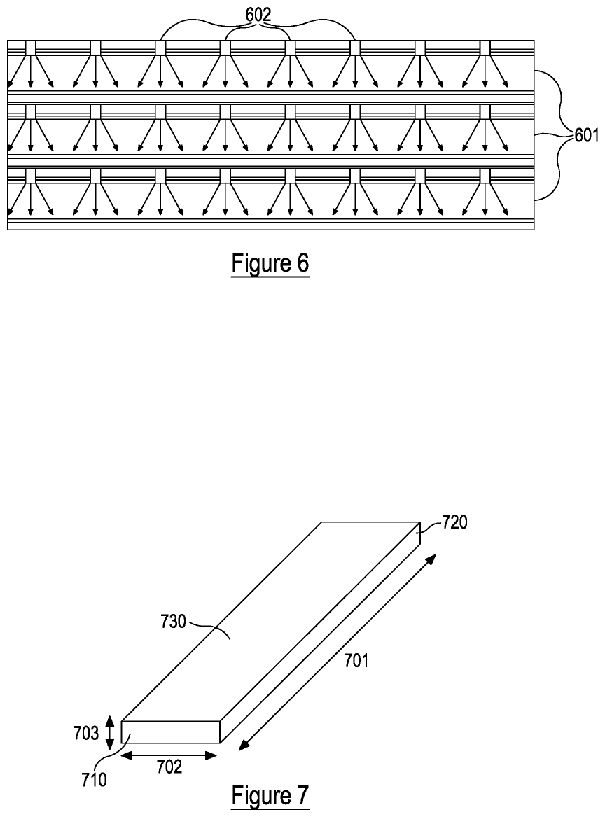

Such an HTS tape may be used to form a buffer-layer insulated HTS coil as described in WO2021/224279, which will result in a buffer layer insulated coil which is a partially insulated coil similar to those described in WO2019/150123. The result is an HTS coil as shown in FIG. 6, where each turn 601 has a radial conductive path to each other turn via the holes 602 and the copper cladding and/or substrates (e.g. where the holes are blind holes into the substrate). The coil may be insulated at the edges such that the buffer layers extend to the insulation or each side of the coil, meaning that the only conductive radial paths past the buffer layer are via the conductive elements in each hole. A similar construction may be applied to an HTS cable formed from the tape, i.e. such that the only conductive paths across or through the buffer layers of each HTS tape in the cable are via the conductive elements, removing the need for conductive edging to connect turns of the cable.

Where terms such as “length”, “width”, “depth” or similar are used in this specification, they refer to particular directions relative to the HTS tape as are conventionally used in the art and shown in FIG. 7. “Length”, “along”, or similar wording refers to features or measurements extending along the longest principal axis of the HTS tape, parallel to the plane of the HTS material layer in the tape (701). “Width”, “across”, or similar wording refers to the direction perpendicular to “length” while still parallel to the plane of the HTS material (702). “Thickness”, “through”, or similar wording refers to the direction perpendicular to both “width” and “length”, and perpendicular to the plane of the HTS material layer (703). The sides of the HTS tape separated in the length direction 701 are the “ends” 710, the sides of the HTS tape separated by the width dimension 702 are the “edges” 720, and the sides separated by the thickness dimension 703 are the “faces” 730. While these are defined for a flat HTS tape, they apply equally where the tape is curved—e.g. for a tape wound into a circle about an axis parallel to its width, the length of the tape extends around the circle and each of the faces forms a cylinder.

While the above has mainly referred to ReBCO tapes, it should be appreciated that the same techniques may be applied to similarly constructed HTS tapes using alternative HTS materials, e.g. those using iron-based superconductors.

1. A high temperature superconducting, HTS, tape comprising:
a superconducting layer formed from HTS material;
a substrate;
one or more buffer layers separating the superconducting layer from the substrate;
a plurality of holes extending at least through the superconducting layer and the one or more buffer layers;
conductive material within each hole, the conductive material providing an electrical connection to the superconducting layer through the one or more buffer layers via the hole.

2. The HTS tape according to claim 1, wherein each hole extends through the substrate.

3. The HTS tape according to claim 1, wherein each hole extends at most partially into the substrate.

4. The HTS tape according to claim 1, wherein the holes are located such that the HTS of the superconducting layer forms a connected surface and/or such that all parts of the HTS are electrically connected to the ends of the tape via the HTS layer.

5. The HTS tape according to claim 1, wherein each hole is one of:
a hole with a substantially circular cross section;
a striation extending along the HTS tape; or
a striation extending only partly along the HTS tape.

6. The HTS tape according to claim 1, wherein one or more of the size, shape, spatial density and/or spacing of the holes varies along the length of the HTS tape.

7. The HTS tape according to claim 1, wherein the conductive material substantially fills each hole.

8. The HTS tape according to claim 1, wherein the conductive material provides an electrical connection between the superconducting layer and the substrate via the hole.

9. The HTS tape according to claim 1, wherein the conductive material is one of: a metal; a metal alloy; silver; copper; solder; a semiconductor; a metal-insulator transition material; or a composite material.

10. The HTS tape according to claim 1, wherein each hole has a minimum width of between 1 micrometre and 1 millimetre, more preferably 10 and 100 micrometres.

11. A method of modifying an HTS tape, the method comprising:
providing an HTS tape, the HTS tape having:
a superconducting layer formed from HTS material;
a substrate; and
one or more buffer layers separating the superconducting layer from the substrate;
forming a plurality of holes through at least the HTS layer and buffer layers of the HTS tape; and
providing conductive material within each hole, such that the conductive material provides an electrical connection to the superconducting layer through the one or more buffer layers via the hole.

12. The method according to claim 11, wherein forming the plurality of holes comprises one or more of:
chemical etching of the HTS layer and/or buffer layer;
mechanical etching of the HTS layer and/or buffer layer;
ablative cutting of the HTS tape and/or buffer layer.

13. The method according to claim 12, wherein forming the plurality of holes comprises chemical etching of the HTS layer to form a plurality of first holes, and ablative cutting or mechanical etching of the buffer layer and optionally the substrate to form a plurality of second holes, each second hole having a cross section which is smaller than the cross section of a respective first hole in the HTS layer, and wherein each second hole is located at the bottom of the respective first hole in the HTS layer.

14. The method according to claim 11, wherein the step of providing conductive material within the holes comprises substantially filling the holes with the conductive material.

15. The method according to claim 11, wherein the conductive material provides an electrical connection between the superconducting layer and the substrate via the hole.

16. A High Temperature Superconductor, HTS, field coil, the HTS field coil comprising windings of one or more HTS tapes about an axis of the coil, wherein the or each HTS tape is an HTS tape according to claim 1.

17. The HTS field coil according to claim 16, wherein at least one of the one or more HTS tapes is configured such that the only electrically conductive pathways extending radially across or through the buffer layer for one or more of the windings are the conductive material within each hole.

18. The HTS field coil according to claim 16, wherein the or each HTS tape has a greater density of holes within a region of the HTS field coil which contains a joint between HTS tapes or cables than in a region of the HTS field coil which does not contain a joint.

19. The HTS field coil according to claim 18, wherein the or each HTS tape does not have holes within the region of the HTS field coil which does not contain a joint.

20. A method of manufacturing a high temperature superconducting, HTS, tape, the method comprising:
providing a substrate having a plurality of holes extending from a first surface of the substrate at least part way through the substrate;
depositing one or more buffer layers on the first surface of the substrate;
depositing a high temperature superconducting, HTS, material on the buffer layers;
such that the buffer layers and HTS material are not deposited over the holes in the substrate;
providing conductive material within the holes, such that the conductive material provides an electrical connection to the HTS material through the one or more buffer layers via the hole.

21. A high temperature superconducting, HTS, cable comprising a plurality of HTS tapes according to claim 1.

22. The HTS cable according to claim 21, wherein at least one of the one or more HTS tapes is configured such that the only electrically conductive pathways extending across or through the buffer layer for one or more of the HTS tapes are the conductive material within each hole.
